(19) United States
(12) Patent Application Publication
(10) Pub. No.: US 2026/0349016 A1
(43) Pub. Date: Nov. 5, 2026

(54) SIGNAL CONDITIONING OF AN ACOUSTICALLY DRIVEN FERROMAGNETIC RESONANCE SENSOR DEVICE

(71) Applicant: Sonera, Inc., Berkeley, CA (US)

(72) Inventors: Dominic LABANOWSKI, Berkeley, CA (US); James R. BLODGETT, Walnut Creek, CA (US); Jonathan KATZ, Oakland, CA (US)

(21) Appl. No.: 19/490,364

(22) PCT Filed: Jun. 7, 2024
(86) PCT No.: PCT/US2024/033159

§ 371 Date: Dec. 4, 2025

Related U.S. Application Data
(60) Provisional application No. 63/506,747, filed on Jun. 7, 2023.

(51) Int. Cl. G01R 29/08

(52) U.S. Cl. CPC G01R 29/0892; G01R 29/0878

(57) ABSTRACT

Systems and methods for signal conditioning of an acoustic driven ferromagnetic resonance (ADFMR) sensor device to improve the performance of the sensor. The apparatuses (e.g., system, devices, etc.) and methods described herein can preferably measure an EM field using magnetic resonance and then utilize this information to determine the magnitude and/or gradient of the field. In particular, any of these systems and methods may include one or more of: low-frequency cancellation (e.g., DC cancellation), RF subtraction, frequency modulation, and the use of one or more pilot tones (e.g., Walsh codes, etc.), either individually or in combination.

### CLAIM OF PRIORITY

This patent application claims priority to U.S. provisional patent application no. 63/506,747, titled “SYSTEM AND METHOD FOR SIGNAL CONDITIONING OF AN ADFMR SENSOR DEVICE,” filed on Jun. 7, 2023, and herein incorporated by reference in its entirety.

### BACKGROUND

Recent research has explored use of acoustically driven ferromagnetic resonance (ADFMR) devices as highly sensitive magnetic sensors. ADFMR sensors may provide highly sensitive magnetic field sensors. These sensors may have a large absorption efficiency and therefore sensitivity as the magnetic film enters resonance. By biasing the device in this region of operation near resonance, the slope of transmitted power as a function of externally applied magnetic field can be extremely steep. These sensors can be used at room temperature and may be manufactured relatively inexpensively.

However, ADFMR devices have technical challenges in realizing practical mass-produced sensors that are usable in a variety of environments. For example, temperature effects may be significant on an ADFMR sensor. In addition, operation of the ADFMR sensor may pose some unique signal processing challenges. Thus, there is a need in the magnetic sensor field to create a new and useful ways to address the signal conditioning needed to improve ADFMR sensor device operation. The methods and apparatuses described herein may address these needs.

### SUMMARY OF THE DISCLOSURE

Described herein are systems and methods for improving the performance of an acoustic driven ferromagnetic resonance (ADFMR) sensor apparatuses. The apparatuses (e.g., system, devices, etc.) and methods described herein can improve the operation of the ADFMR sensors described herein by including one or more of: low-frequency cancellation (e.g., DC cancellation), RF subtraction, frequency modulation, and the use of one or more pilot tones (e.g., Walsh codes, etc.), either individually or in combination.

In general, the methods and apparatuses described herein may relate to the field of magnetic sensor systems and more specifically to new and useful systems and methods for signal conditioning in an ADFMR sensor devices. These apparatuses may generally include an input oscillator, which may be configured as an RF input, to apply energy to the ADFMR sensor; the ADFMR sensor may modulate the applied energy based on an external magnetic field and this modulation may be decoded using the apparatuses described herein. In general these apparatuses may include a sensing path, including the ADFMR sensor, and one or both of a demodulation path, for demodulating the high-frequency applied energy so that the encoded signal may be more easily manipulated and decoded, and a subtraction path, also referred to in some contexts as a reference path or cancellation path, that may be combined (e.g., summed/subtracted) with the sensing path in order to remove excess carrier power. In some cases the apparatus may include a sensing path and a demodulation path, but not a subtraction path; in some cases the apparatus may include a sensing and a subtraction path, but not a demodulation path.

For example, any of these apparatuses may be configured to include low-frequency cancellation to remove low frequencies (resulting in DC or near-DC voltages) from the signal, particularly following demodulation, to allow greater amplification (e.g., without saturating). In some cases, a system for an acoustically driven ferromagnetic resonance (ADFMR) based measurement of electromatic (EM) fields may include: a power splitter configured to split a high frequency electrical signal into a sensing signal and a demodulation signal; an ADFMR sensor comprising a first electrical transducer coupled to a piezoelectric substrate and configured to receive the sensing signal, a magnetostrictive material on the substrate, and a second electrical transducer coupled to the piezoelectric substrate and configured to output a modulated sensing signal; a mixer configured to combine a signal from the modulated sensing signal with the demodulation signal, the mixer having an output; a low-frequency cancellation sub-system or module (also referred to herein as a DC cancellation sub-subsystem or module) coupled to the output of the mixer and configured to remove a very low frequency (e.g., 0.5 Hz or less, including DC) components at the output of the mixer to remove these lower frequency components. The device may include a detector that determines the EM field from the output after low-frequency cancellation.

For example, these apparatuses may generally include a sensing (e.g., test) path between the splitter and the mixer/detector that may be electrically parallel with demodulation path. The low-frequency cancellation sub-system, which may include or be referred to as a low-frequency cancellation module (e.g., low-frequency cancellation circuit or sub-system), may be coupled between the mixer (e.g., an IQ mixer) and the detector.

The low-frequency cancellation sub-systems described herein may be part of a system including a sensing path and a demodulation path; optionally these apparatus may include a subtraction path. In some examples the low-frequency cancellation sub-system (e.g., low-frequency cancellation circuit) may comprise a set of baseband amplifiers coupled to a mixer (e.g., an IQ mixer). In some cases the low-frequency cancellation sub-system may be configured to sample the output of the baseband amplifiers and apply a correction signal to the inputs of the baseband amplifiers to null the output voltages within a certain frequency bandwidth (e.g., from DC to 100 Hz, from DC to 10 Hz, from DC to 5 Hz, from DC to 1 Hz, from DC to 0.5 Hz, etc.). In some cases the low-frequency cancellation sub-system may comprise a set of lowpass filters and baseband amplifiers coupled to an IQ mixer.

Any of the system described herein may include a time delay circuit any of the sensing path, subtraction path and/or demodulation path configured to receive and delay a signal in this path. The time delay circuit may comprise a surface acoustic wave (SAW) delay device. In some cases the delay circuit comprises a second SAW device, e.g., using the same piezoelectric substrate or a different piezoelectric substrate configured to receive the demodulation signal, wherein the second piezoelectric has dimensions similar to the piezoelectric of the ADFMR sensor. Other time delay elements may be used. Optionally no separate time delay element may be used.

In general, any of the low-frequency cancellation sub-systems described herein may beneficially include a reset function configured to zero a DC output of the low-frequency cancellation sub-system quickly (e.g., within less than 10 milliseconds, less than 5 milliseconds, less than 1 millisecond, etc.). In some cases the low-frequency cancellation sub-system comprises a microprocessor configured to adjust a cut-off frequency of the low-frequency cancellation sub-system. The microprocessor may be specific to the low-frequency cancellation sub-system, or it may be shared with other sub-systems, including (but not limited to) the output detector that determines the EM field from the output after low-frequency cancellation. The low-frequency cancellation sub-system may be configured to adjust a capacitance and/or a resistance of the low-frequency cancellation sub-system to zero a DC output of the low-frequency cancellation sub-system.

Thus, any of the apparatuses (e.g., systems) and methods described herein may include RF subtraction, as mentioned above. For example, a system for an acoustically driven ferromagnetic resonance (ADFMR) based measurement of magnetic and/or electromagnetic (EM) fields may include: a power splitter (or series of power splitters) configured to split a high frequency electrical signal into a sensing signal, a demodulation signal, and a subtraction signal (e.g., a test signal); an ADFMR sensor comprising a first electrical transducer coupled to a piezoelectric substrate and configured to receive the sensing signal, a magnetostrictive material on the substrate, and a second electrical transducer coupled to the piezoelectric substrate and configured to output a modulated sensing signal; a power combiner configured to sum the modulated sensing signal and the subtraction (e.g., test) signal to output a subtracted sensing signal; a mixer configured to combine the subtracted sensing signal with demodulation signal, the mixer having an output; and a detector that determines the EM field from the output of the mixer.

Any of these apparatuses may include a frequency modulation circuit in line with the RF subtraction circuit and configured to modulate one or both of the phase and amplitude of the demodulation signal. For example, the apparatus may include a power source comprising an oscillator configured to provide the electrical signal to the power splitter.

Also described herein are apparatuses including frequency tuning to modify the frequency of the original high frequency electrical signal (e.g., from the RF input oscillator) to leverage the time delay difference between the ADFMR sensor path and the subtraction path to induce a phase shift between the paths. For example, a system for an acoustically driven ferromagnetic resonance (ADFMR) based measurement of magnetic and/or electromagnetic (EM) fields may include: a power splitter configured to split a high frequency electrical signal into a sensing signal and a demodulation signal; an ADFMR sensor comprising a first electrical transducer coupled to a piezoelectric substrate and configured to receive the sensing signal, a magnetostrictive material on the substrate, and a second electrical transducer coupled to the piezoelectric substrate and configured to output a modulated sensing signal (which may also be referred to herein as an excitation signal) from the sensing path; a frequency tuning module configured to modulate the RF input oscillator; a combiner to combine the modulated sensing signal with the output of the subtraction signal (from the subtraction path), and a mixer having an output, that is configured to mix (e.g., multiply) the demodulation signal with the summed/subtracted sensing signal; and a detector that determines the EM field from the output of the mixer.

Any of these devices may include one or more oscillators configured to modulate and/or vary the phase of the signal applied to the sensor, reference or mixer LO, or all three. For example, the demodulation signal (from the demodulation path) may shift the relative phase and signal power between the reference and sensor paths. In some cases the one or more oscillators is one or more of: a voltage controlled oscillator (VCO), digitally controlled oscillator (DCO), or temperature controlled oscillator (TCO). Any of these apparatuses may include one or more phase and/or amplitude control module. The phase and/or amplitude control module may be configured to modulate either or both the phase and amplitude of one of the subtraction path, the sensing path or the demodulation path. For example, a frequency modulation circuit may include a coarse amplitude and phase control and a fine amplitude and fine phase control, as part of a phase and/or amplitude module.

Any of these apparatuses including a phase and/or amplitude control module may be configured to more accurately and effectively control the attenuator (amplitude) and/or phase of a signal in-line with the phase and/or amplitude control module. In any of these examples, the device may include a pilot tone module that is configured to apply one or more pilot tones and/or an orthogonal code, such as a Walsh code. The pilot tone module may also be referred to herein as a code circuit or code module and may include a microcontroller and/or oscillator. The pilot tone module may be configured to control the amplitude trimmer and/or phase trimmer (e.g., to adjust the fine frequency and the fine phase control, which may be part of the phase and/or amplitude control module. For example, the pilot tone module may comprise one or more oscillators configured to control the fine amplitude control, fine frequency control and the fine phase control. In some examples, the pilot tone module may comprise an integrated fractional-N (Frac-N) frequency synthesizer or an Integer-N system. In some cases the pilot tone module comprises a code generator to modulate one or both of the relative phase and relative amplitude of the demodulation signal compared to the sensor signal; for example, the code generator may comprise a Walsh code generator. The pilot tone module may be part of a microcontroller. In some cases the pilot tone module may include one or more circuits configured to apply one or more pilot tones to the demodulation signal. For example, the pilot tone module may comprise a microcontroller configured to set the one or more pilot tones; the one or more pilot tones may be one of: a Walsh code, a Gold code, etc.

For example, described herein are systems for an acoustically driven ferromagnetic resonance (ADFMR) based measurement of electromatic (EM) fields, the system comprising: a power splitter configured to split a high frequency electrical signal into a sensing signal and a demodulation signal; an ADFMR sensor comprising a first electrical transducer coupled to a piezoelectric substrate and configured to receive the sensing signal, a magnetostrictive material on the substrate, and a second electrical transducer coupled to the piezoelectric substrate and configured to output a modulated sensing signal; a mixer configured to combine a signal from the modulated sensing signal with the demodulation signal, the mixer having an output; a low-frequency cancellation sub-system coupled to the output of the mixer and configured to remove a DC or near-DC voltage component of the output of the mixer; and a detector that determines the EM field from the output after low-frequency cancellation.

Any of these systems may include a power source comprising an oscillator configured to provide the electrical signal to the power splitter. The low-frequency cancellation sub-system may comprise a set of baseband amplifiers coupled to an I channel and a Q channel of the mixer (e.g., the mixer may be an I/Q mixer).

The low-frequency cancellation sub-system may be configured to sample the output of the baseband amplifiers and apply a correction signal to the inputs of the baseband amplifiers to null the output voltages. In some cases the low-frequency cancellation sub-system may comprise a set of lowpass filters and baseband amplifiers coupled to an I channel and a Q channel of the mixer. Any of these low-frequency cancellation sub-system may comprise a reset function configured to zero an output of the low-frequency cancellation sub-system within less than 10 milliseconds.

The low-frequency cancellation sub-system may comprise a microprocessor configured to adjust a cut-off frequency of the low-frequency cancellation sub-system. In some examples the low-frequency cancellation sub-system may be configured to move frequencies of less than 0.5 Hz from the output of the mixer (e.g., between 0.5 Hz and 100 kHz, between 0.5 kHz and 10 kHz, between 0.5 kHz and 1 kHz, etc.).

The low-frequency cancellation sub-system may comprise an adjustable capacitance and/or a resistance configured to be adjusted to zero a low-frequency output.

Also described herein are apparatuses configured to include frequency tuning. In particular, these apparatuses may be configured to tune the local oscillator (LO) of the demodulation path in order to modulate the phase of the subtraction path that is combined with the sensing path. For example, a system for an acoustically driven ferromagnetic resonance (ADFMR) based measurement of electromatic (EM) fields may include: a high-frequency electrical oscillator; a first power splitter configured to split a high frequency electrical signal from the high-frequency electrical oscillator between a demodulation path and a second power splitter; wherein the second power splitter is configured to further split the high-frequency electrical signal from the first power splitter between a sensing path and a subtraction path; an ADFMR sensor in the sensing path, the ADFMR sensor comprising a first electrical transducer coupled to a piezoelectric substrate and configured to receive a sensing signal, a magnetostrictive material on the substrate, and a second electrical transducer coupled to the piezoelectric substrate and configured to output a modulated sensing signal; a combiner combining the modulated sensing signal from the sensing path and a signal from the subtraction path; a mixer configured to combine an output of the combiner with an output of the demodulation path; a frequency tuning module in communication with the high-frequency electrical oscillator and configured to modulate the high-frequency electrical oscillator; and a detector that determines the EM field from an output of the mixer.

The high-frequency electrical oscillator may be a radio-frequency (RF) oscillator. The frequency tuning module may receive control input from a controller. The frequency tuning module may be configured to adjust the phase of the signal from the subtraction path by adjusting the frequency of the high-frequency oscillator. Any of these systems may include a low-frequency cancellation module between the mixer and the detector. Any of these systems may include a phase and/or amplitude control module in one or more of: the sensing path, the subtraction path and/or the demodulation path. The phase and/or amplitude control module may be configured to adjust phase and/or amplitude of the corresponding path. For example a system may include a phase and/or amplitude control module in the subtraction path, wherein the phase and/or amplitude control module is configured to adjust phase and/or amplitude of the signal from the subtraction path. The phase and/or amplitude control module may comprise an attenuator trimmer and a phase trimmer.

Any of these systems may include a pilot tone module in communication with the phase and/or amplitude control module, wherein the pilot tone module is configured to apply one or more pilot tones to an attenuator trimmer and a phase trimmer of the phase and/or amplitude control module. The pilot tone module may be configured to apply an orthogonal code. The orthogonal code may a Walsh code, a Gold code, etc. As described herein, the orthogonal code may be considered a subtype of the pilot tone, and the pilot tone module may be configured to apply the orthogonal code (e.g., the Walsh code).

Any of these apparatuses may be configured to include a power detector downstream of the combiner and configured to adjust the pilot tone module. The power detector may provide input to a controller (e.g., microprocessor unit, MCU, or the like) that may be used to modulate the pilot tone module operation.

In general, any of the pilot tone modules may receive control input from and/or may include one or more controllers (that may be configured to control the pilot tone module operation). The pilot tone module may include and/or may be configured to operate with one or more oscillators.

For example, a system for an acoustically driven ferromagnetic resonance (ADFMR) based measurement of electromatic (EM) fields may include: a high-frequency electrical oscillator; a first power splitter configured to split a high frequency electrical signal from the high-frequency electrical oscillator between a demodulation path and a second power splitter; wherein the second power splitter is configured to further split the high-frequency electrical signal from the first power splitter between a sensing path and a subtraction path; an ADFMR sensor in the sensing path, the ADFMR sensor comprising a first electrical transducer coupled to a piezoelectric substrate and configured to receive a sensing signal, a magnetostrictive material on the substrate, and a second electrical transducer coupled to the piezoelectric substrate and configured to output a modulated sensing signal; a phase and/or amplitude control module in the subtraction path, wherein the phase and/or amplitude control module is configured to adjust a phase trimmer and an attenuation trimmer of the subtraction path; a combiner combining the modulated sensing signal from the sensing path and a signal from the subtraction path; a mixer configured to combine an output of the combiner with an output of the demodulation path; a frequency tuning module in communication with the high-frequency electrical oscillator and configured to modulate the high-frequency electrical oscillator; and a detector that determines the EM field from an output of the mixer.

Thus, described herein are apparatuses (e.g., systems) that apply one or more pilot tones to control tuning (e.g., fine tuning) of the phase and amplitude of the sensing path and/or the subtraction path. For example, a system for an acoustically driven ferromagnetic resonance (ADFMR) based measurement of electromatic (EM) fields, the system comprising: a power splitter configured to split a high-frequency electrical signal from between a sensing path and a subtraction path; an ADFMR sensor in the sensing path, the ADFMR sensor comprising a first electrical transducer coupled to a piezoelectric substrate and configured to receive a sensing signal, a magnetostrictive material on the substrate, and a second electrical transducer coupled to the piezoelectric substrate and configured to output a modulated sensing signal; a phase and/or amplitude control module in the sensing path or the subtraction path, wherein the phase and/or amplitude control module is configured to adjust phase and/or amplitude of the sensing path or the subtraction path; a combiner combining the modulated sensing signal from the sensing path and a signal from the subtraction path; and a detector that determines the EM field based on an output of the combiner.

The phase and/or amplitude control module may be in the subtraction path, and the phase and/or amplitude control module may be configured to adjust phase and/or amplitude of the signal from the subtraction path. The phase and/or amplitude control module may include an attenuator trimmer and a phase trimmer.

Any of these apparatuses may include a pilot tone module in communication with the phase and/or amplitude control module, wherein the pilot tone module is configured to apply one or more pilot tones to an attenuator trimmer and a phase trimmer of the phase and/or amplitude control module.

The pilot tone module may be configured to apply an orthogonal code. The orthogonal code may comprise a Walsh code. Any of these devices may include a power detector downstream of the combiner and configured to adjust the pilot tone module. The device may include a controller configured to control the pilot tone module. The pilot tone module may comprise one or more oscillators.

A system for an acoustically driven ferromagnetic resonance (ADFMR) based measurement of electromatic (EM) fields may include: a power splitter configured to split a high-frequency electrical signal from between a sensing path and a subtraction path; an ADFMR sensor in the sensing path, the ADFMR sensor comprising a first electrical transducer coupled to a piezoelectric substrate and configured to receive a sensing signal, a magnetostrictive material on the substrate, and a second electrical transducer coupled to the piezoelectric substrate and configured to output a modulated sensing signal; a phase and/or amplitude control module in the sensing path or the subtraction path, comprising an attenuation trimmer and a phase trimmer configured to adjust phase and/or amplitude of the sensing path or the subtraction path; a combiner combining the modulated sensing signal from the sensing path and a signal from the subtraction path; a pilot tone module in communication with the phase and/or amplitude control module, wherein the pilot tone module is configured to apply one or more pilot tones to the attenuator trimmer and the phase trimmer of the phase and/or amplitude control module; and a detector that determines the EM field based on an output of the combiner.

Also described herein are methods of operating any of these systems, and software (e.g., computer-readable storage medium storing a set of instructions for the processes of any of these methods).

All of the methods and apparatuses described herein, in any combination, are herein contemplated and can be used to achieve the benefits as described herein.

### BRIEF DESCRIPTION OF THE DRAWINGS

A better understanding of the features and advantages of the methods and apparatuses described herein will be obtained by reference to the following detailed description that sets forth illustrative embodiments, and the accompanying drawings of which:

FIG. 1A is a schematic representation of one example of an ADFMR sensor system having a subtraction path and a sensing path.

FIG. 1B schematically illustrates another example of an ADFMR sensor system, including a sensing path, a subtraction path and a demodulation path, each of which may include various components some of which are optional.

FIG. 2A is a schematic representation of a system including a low-frequency cancellation module.

FIG. 2B is another example of a system including a low-frequency cancellation module (e.g., circuit).

FIG. 3 is a schematic representation of a device including an ADFMR sensor with a phase and/or amplitude control sub-system.

FIG. 4 is a schematic representation of incorporating a SAW device in a reference path.

FIG. 5 is a schematic representation of incorporating phase and amplitude control in the reference path.

FIGS. 6 and 7 are schematic representations of variations using pilot tones.

FIG. 8 is a schematic representation of a variation with a pilot tone (e.g., Walsh code) subsystem.

FIG. 9 is a flowchart representation of a dithering and phase reset processes used in a Walsh code variation.

FIG. 10 is a schematic representation of one example of an ADFMR sensor system as described herein.

### DETAILED DESCRIPTION

Acoustically driven ferromagnetic resonance (ADFMR) sensing is driven by dynamic strain/stress fields and spin-wave amplitudes local to the magnetoelastic film/driving piezoelectric interface. A typical configuration for the measurement of this phenomenon consists of an input and output interdigitated transducer (IDT) on a piezoelectric substrate, with a thin magnetostrictive film (e.g., ferromagnetic film) deposited between the two. Acoustic waves (e.g., surface acoustic waves, SAWs, or bulk waves) generated by an AC voltage incident on the input IDT travel through the substrate, where some of the SAW power is absorbed by the magnetostrictive material, driving it into resonance. The remaining SAW power continues to propagate through the substrate until it reaches the output IDT, where it is converted back into an AC voltage. The magnitude of absorption by the magnetic film is used to characterize the effect and provides a readout of any external magnetic field, which may modulate the magnetostrictive film.

Thus, an output signal from the sensor may be a relatively small amplitude modulated (AM) signal on a much larger radio frequency (RF) carrier. It may be particularly challenging to detect and process these signals in the context of an ADFMR sensor. This may be due in part because of the large discrepancy between the AM and carrier signals as well as the operation of the ADFMR sensor itself. The methods and apparatuses described herein may allow the detection and amplification of the output signal in the context of an ADFMR sensor.

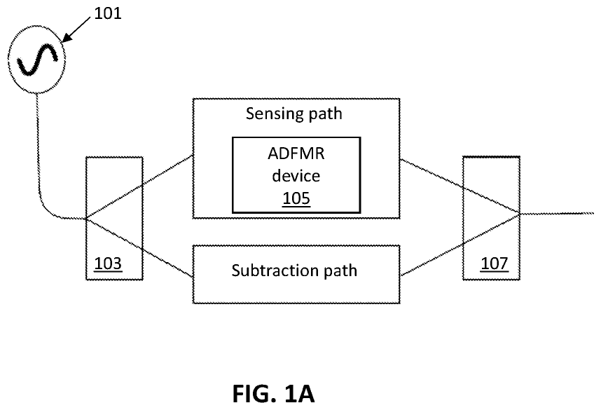

A system and method for signal conditioning of an ADFMR sensor device functions to facilitate one or more different enhancements for an improved magnetic sensor. The apparatuses (e.g., system, devices, etc.) and methods described herein can preferably measure an EM field using magnetic resonance and then utilize this information to determine the magnitude and/or gradient of the field. In one example shown in FIG. 1A, a system and method may include a voltage oscillator, operating in the order of MHz-GHz that generates an oscillating signal; a power splitter that splits the oscillating signal into a sensing signal (in the sensing path) and a subtraction signal (in the subtraction path); an ADFMR circuit comprising of an acoustic driven ferromagnetic resonance (ADFMR) sensor device; wherein the magnetostrictive material of the ADFMR sensor may alter the sensing signal with respect to a magnetic field; a combiner 107 combining the sensing signal and the subtraction signal, and a detector that uses the altered sensing signal and demodulation signal to determine the magnitude and/or gradient of the magnetic field. The subtraction signal may be processed or altered through reference circuitry configured in some way. The detector may include an analog-to-digital converter (ADC) and may include additional amplification or signal processing. The detector (e.g., signal detector) may measure the output power signal. Since the output power signal may have been perturbed by the sensed magnetic field, the output power signal may be used to determine the EM field strength. The signal detector may additionally include noise reduction functionalities. In some variations, the signal detector may perform a Fourier transform to separate the desired output signal from other extraneous Electromagnetic (EM) waves. For example, an input acoustic transducer may additionally generate extraneous EM waves. The signal detector may perform a Fast Fourier Transform to isolate and remove these extraneous waves from the desired signal.

In some cases the device may include a third pathway, a demodulation pathway. See, e.g., FIG. 1B. The demodulation pathway may split from the applied RF input 101, and may be used to demodulate the sensing signal after it has been summed (subtracted by) the subtraction signal, in examples including a subtraction pathway.

The systems and methods for signal conditions of an ADFMR device described herein may include one of a set of different system enhancements that can improve signal output. For example, as described herein, these systems and methods may employ one or more of: low-frequency cancellation, RF (Radio Frequency) subtraction, frequency modulation, pilot tones, Walsh codes, and/or other approaches. These system and method variations in some variations may be used in combination.

These systems and methods may incorporate additional design variations of an ADFMR sensor circuit or device such as those described in U.S. Publication No. US2021/181132A1 , filed Dec. 14, 2020, titled “System and Method for an Acoustically Driven Ferromagnetic Resonance Sensor Device,” which is hereby incorporated in its entirety by this reference.

In general, these systems and methods described herein may provide a number of potential benefits, but are not limited to always providing such benefits and are presented only as exemplary representations for how the system and method may be put to use. The list of benefits is not intended to be exhaustive and other benefits may additionally or alternatively exist.

As one potential benefit, the systems and methods described herein may address the signal conditioning challenges of conditioning a sensing signal output (from a first path containing a primary ADFMR sensor) in relation to a demodulation signal output (from a second path). As another potential benefit, these systems and methods may address potential temperature-sensitivity of an ADFMR device. ADFMR sensor elements may be particularly sensitive to changes in temperature. Variations of these systems and methods can resolve such issues and result in an ADFMR sensor with improved performance in varying environments. As another potential benefit, these systems and methods may counteract, or address challenges related to an inherent time delay of an ADFMR sensing device. A surface acoustic wave (SAW) device used in an ADFMR sensor may have time delays resulting from operating based on an acoustical interaction. This time delay can introduce a phase shift between a sensing signal and a demodulation signal, and the various system design variations described herein may address such phase shifts.

FIG. 1A shows one example of a system for signal conditioning an ADFMR sensor; this system may include a voltage oscillator 101, operating in the order of MHz-GHz that generates an oscillating signal (e.g., an RF carrier); a power splitter 103 that splits the oscillating signal into a sensing signal and a demodulation signal; an ADFMR circuit 105 comprising of an acoustic driven ferromagnetic resonance (ADFMR) device; wherein the ADFMR device alters the sensing signal with respect to an external magnetic field; and a combiner 107 and a detector that uses the altered sensing signal and demodulation signal to determine the magnitude and/or gradient of the magnetic field. The subtraction signal may also preferably be processed or altered through reference circuitry configured with supplemental components as detailed in the variations herein.

Any of the variations of these systems and methods may include one or more of: a low-frequency cancellation subsystem or configuration, a RF (Radio Frequency) subtraction subsystem or configuration, a frequency tuning subsystem or configuration, a pilot tone subsystem or configuration (which may be configured as a Walsh code subsystem or configuration), and/or other signal processing subsystems or components. These system variations may be used in various combinations.

FIG. 1B schematically illustrates an example of a system including many of these components that may be optionally included. Optional components are shown by dashed lines. Although optional, some of these components may be more useful than others, and certain combinations may perform surprisingly better than unmodified forms of the invention. In FIG. 1B the system includes an RF input 101 that is initially divided by splitter 102 into the demodulation path (e.g., “A”) and a second power splitter 102′ that again divides the input signal into a sensing path (“B”) and a subtraction path (“C”). In some cases the demodulation path, A, is not included but the subtraction path, C, is; in some cases the subtraction path, B, is not included but the demodulation path, A, is. In FIG. 1B the sensing path includes the ADFMR sensor 105 and may include one or more phase and/or amplitude control modules 135, which may include an attenuation trimmer 136, 136′, 136″ and/or a phase trimmer 137, 137′, 137″. Other features may be included as well. The subtraction path may optionally include a phase and/or amplitude control module 135′. In some cases the apparatus may also include a pilot tone module 142 (and a controller 144 and/or oscillator 143, which may be part of the pilot tone module 142 or may be separate). The sensing path and the subtraction path may be combined in the combiner 107. In FIG. 1B the system may also include a demodulation path, A, which may include one or more of: a delay element 165′, a phase and/or amplitude control module 135″, a mixer (e.g., IQ Mixer 109), a low-frequency cancellation module 115. The system may also include a frequency tuning module 133 that may be used to tune the frequency applied by the RF input 101. Thus, the system can include modules for low-frequency cancellation. A device implementing such a variation may enable a system capable of fast filtering to suppress transients quickly and slow filtering for low noise during normal operation. In some examples, low-frequency cancellation variation may further include RF subtraction, which may remove carrier remnant artifacts. A mixer (IQ Mixer) 109 may be used to pull the sensed signal down from the high-frequency RF energy input from the oscillator 101. Any of these apparatuses may include an Analog-to-digital converter (ADC) 117, which may feed into the microcontroller 140.

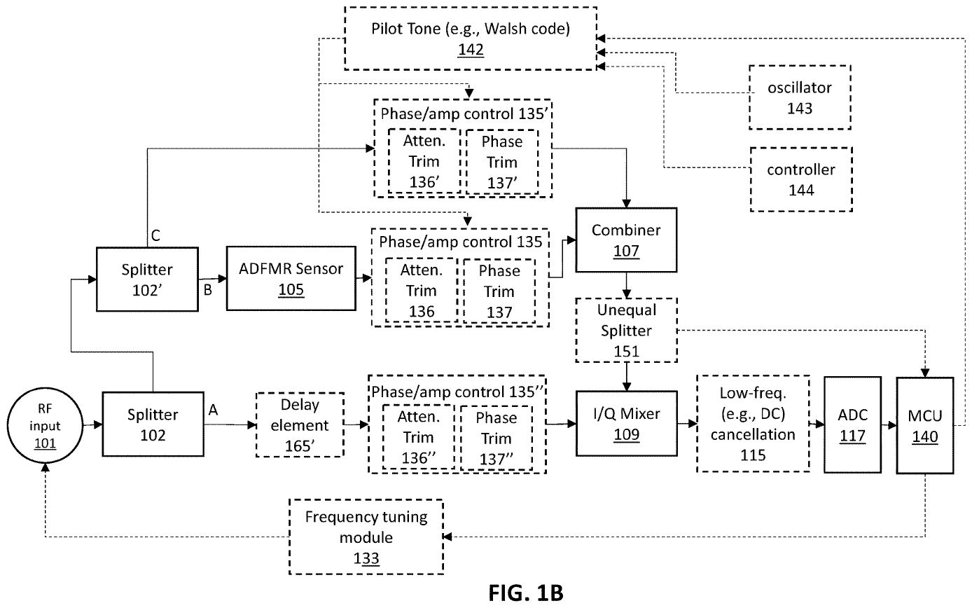

Any of these apparatuses may include a low-frequency cancellation module 115. For example, in some examples a system with low-frequency cancellation may be implemented as shown in the exemplary diagram of FIG. 2A. In some examples, a low-frequency cancellation subsystem subtracts a low (e.g., DC) component of the sensed signal at mixer 209 outputs (I and Q outputs). This may be implemented to allow passage of the desired signals (nominally in the range of 1 Hz to 1 kHz) while substantially removing lower frequency components. low-frequency cancellation is done simply by sampling the output of baseband amplifiers and applying a correction signal to the inputs to null the output voltages. This may effectively result in a high-pass response which passes signals greater than a cut-off frequency, but eliminates signals below the cut-off frequency. Because of the low cut-off frequency, the response time to a step change in the measured signal can be long (multiple seconds). For this reason, there may also be a reset function that can be used to very quickly (milliseconds) zero the lower frequency (e.g., DC output, output less than 0.5 Hz, etc.). This might be used on a frame-by-frame basis or only when needed. This reset function can be implemented by programmably adjusting the cut-off frequency of the low-frequency cancellation circuit. In some variations, this can be done by adjusting the capacitance of the feedback circuits. In some variations, this can be done by adjusting the resistance of the feedback circuits. A combination of both of these techniques can also be used. The example shown in FIG. 2C is very similar to that shown in FIG. 2A, but with the addition of the subtraction path (C), and therefore also includes a subtraction signal and a combiner 207.

In FIG. 2A the RF input 201 is split using a splitter 203 and sent to the sensing signal (e.g., to attenuator 204 and ADFMR sensor 205 to the mixer 209. In FIG. 2B, the first splitter 203 is connected to a second splitter 203′ that forms the subtraction path (C) and the sensor path (B) including the optional attenuator 204 and ADFMR sensor 205, and the sensor path is combined with the subtraction path (subtracting it from the sensing path) at combiner 207 before being sent to the mixer 209 (e.g., IQ Mixer) for multiplication by the local oscillator (LO) signal of the demodulation path (A). As mentioned, the mixer may be an I/Q mixer 209; the LO and Q components are low-pass filtered 213, 213′, and low-frequency cancellation baseband amplifiers, forming the low-frequency cancellation sub-system 215, are applied and passed to the ADC 217 for outputting the signal. Thus, FIGS. 2A and 2B both schematically illustrate examples of low-frequency cancellation sub-systems 215. These low-frequency cancellation sub-systems may generally form filters that zero out the DC and low-frequency (e.g., less than 10 Hz, less than 5 Hz, less than 1 Hz, less than 0.5 Hz, etc.) signal (e.g., voltage/current), and may also prevent, block or zero-out very high frequency signal (e.g., grater than 1 kHz, greater than 10 kHz, greater than 100 kHz, etc.).

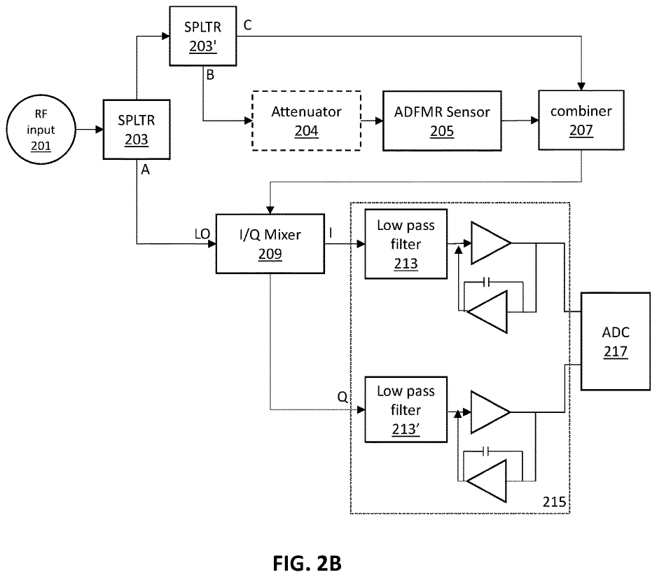

The reference path may include RF subtraction. The RF subtraction reference path may include amplifiers, time delay system (e.g., an additional SAW device), and/or a differential sensor (e.g., time delay +a 2× signal). In one example shown in FIG. 4, a SAW device 431 may be configured within a reference path to produce comparable time delays between the sensing path and the reference path. The reference path may also optionally include phase and amplitude control 430.

As a more detailed explanation, the ADFMR sensor 405 may be a surface acoustic wave (SAW) device and therefore have the propagation velocity of sound in a solid. For a device on a Lithium Niobate substrate with 1 mm between the transducers the time delay is approximately 330 ns. This may be compared to a few ns through the phase and amplitude control/reference path. Cancellation of signals across anything greater than a zero Hz bandwidth benefit from not only phase matching but delay matching. With a roughly 330 ns of delay difference between the paths, the maximum bandwidth that can be cancelled to 60 dB may be about 1 kHz.

If a SAW delay element 431 (e.g., in some examples, a similar ADFMR sensor without the magnetostrictive material/magnetic loading) is included in the reference path such as shown in FIG. 4, this delay difference may be greatly reduced, minimizing this problem. SAW devices may exhibit triple-transit responses where part of the signal effectively travels through the device three times, adding to and subtracting from the single pass signal. Subtracting these triple transit signals from the ADFMR sensor output via inclusion of a SAW delay element may enhance the system's ability to maintain an adequate cancellation depth, as compared to a typical reference path which does not have meaningful triple transit signals.

Thus, the SAW delay element included in the reference path may be a SAW device. A reference path SAW device, in some variations, may be a bare device or a differentially configured sensor. Additionally, by integrating a SAW device in the reference path, temperature effects on the sensor can be reduced or eliminated since the impact of temperature changes (or other environmental conditions) would be the same (or substantially similar) across both channels (e.g., the SAW component in the sensing path as well as the SAW component in the reference path) and thus may cancel each other out. When the reference path SAW device is a differentially configured sensor, the device may act as an ADFMR sensor but with an opposite response to magnetic field (e.g., if the application of a +1 uT magnetic field results in a change in the output of the sensing path ADFMR sensor by +1 mV, the application of a +1 uT magnetic field results in a change in the reference path ADFMR sensor by −1 mV). This may allow for both the matching of time delay and environmental effects as described above, but also may result in a system output to a magnetic field that is 2× larger than a system that contains a single ADFMR sensor (if the magnetic field responses of the two sensors are equal but opposite).

In another example, a system with an RF subtraction reference path may pull a mixer LO off the reference path. In this case, noise generated by the reference path noise will be present on both the mixer RF and LO inputs, and thus may be removable via homodyne downconversion.

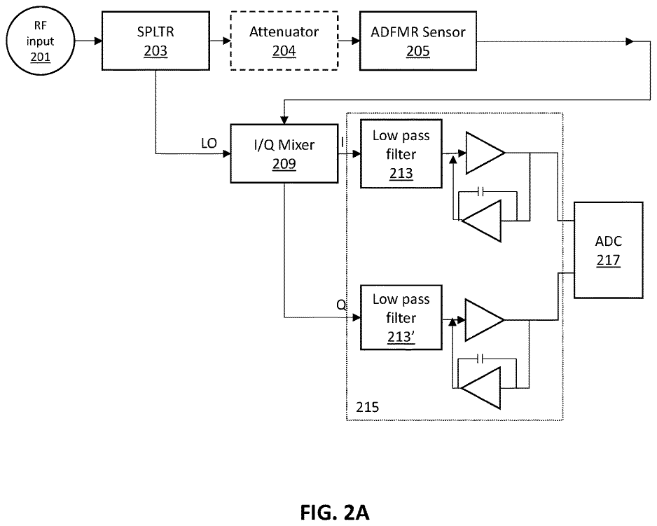

In some variations, the system may include components to enable phase and/or amplitude control, including frequency modulation, of the RF subtraction path (C). For example, FIG. 3 shows one exemplary implementation of RF signal subtraction integrated into the ADFMR sensor system. Such an implementation may remove un-needed parts of the sensor output signal (e.g., removing the RF carrier from the sensing signal output) and leave only desired sidebands. In FIG. 3, this may be accomplished by splitting the input oscillation signal (from the RF input 301) from a first splitter 303 into a demodulation path (A) and an intermediate path that is split (using a second splitter 303′) into the sensing path (B) and a subtraction path (C). The sensing path may include an attenuator 304 prior to an ADFMR sensor 305, that connects to a combiner, combining this portion (e.g., the sensing path signal) with the split portion (the subtraction path). The subtraction path (C) may be modulated by a phase and/or amplitude control 135′; in this example the phase and/or amplitude control includes a digital attenuator 312, an analog attenuator trimmer 313, a digital phase shifter 314 and an analog phase trimmer 315. This configuration, using the subtraction pathway, may result in removal of the carrier power from the modulated signal. With the carrier power removed, the remaining signal may be substantially amplified (e.g., using one or more amplifiers 316), thus minimizing the impact of noise, added by components that follow downstream (the I/Q mixer 309, lowpass filters 325, 325′, baseband amplifiers 336, and ADC 317, etc.). Thus, the sensing signal may have the RF carrier frequency removed and used as an input into an amplifier 316 (e.g., a low noise amplifier, LNA). Eliminating the carrier may also reduce noise introduced by the carrier signal itself, allowing for the detection of signals that would otherwise not be visible above the noise.

As discussed, in some variations a combination of both low-frequency cancellation and RF subtraction may be used. In some examples, a minimum amount of RF subtraction (say, 20 dB) combined with low-frequency cancellation might have advantages, as illustrated in FIG. 3 (e.g., 20 dB coupler 319 and power detector 388).

Optionally, as mentioned above, any of these variations may include components to enable frequency modulation (see, e.g., FIG. 4). A variation with frequency modulation can leverage high time delay in a SAW device and its large phase/frequency coupling to use frequency change to tune phase. This may enable the system to tune phase without including phase tuning components (e.g., digital and/or analog phase shifters) and may use current RF sources.

ADFMR sensors may have a substantially flat amplitude response over a range of +/−MHz. In some variations, this may be tuned or modified depending on implementation.

The ADFMR sensors may, however, have high phase response (e.g., approximately 120 degrees/MHz) in a corresponding frequency range. This may similarly be tuned or modified depending on implementation. A reference path of a circuit (e.g., with integrated circuit components or fixed attenuation and/or phase) may have minimal frequency dependence.

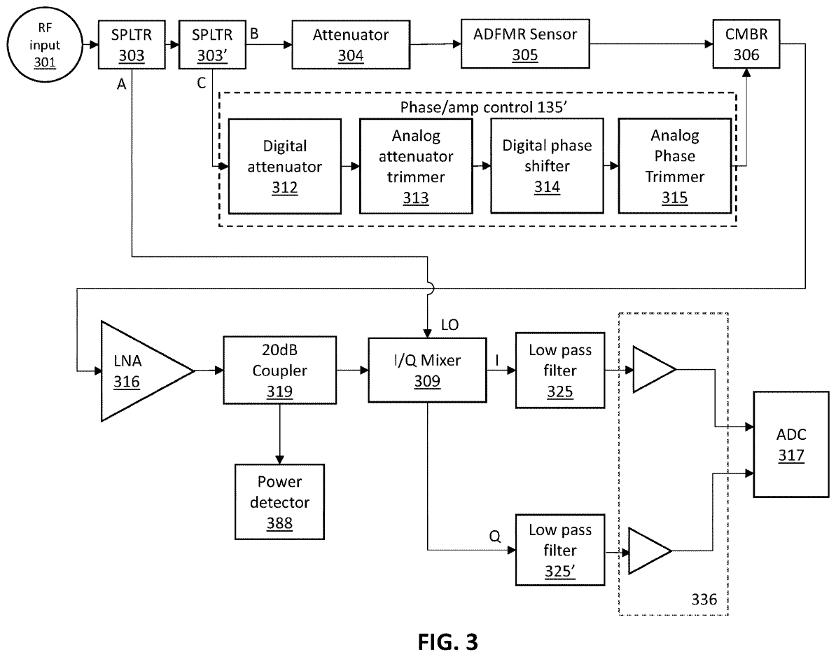

In some variations, delay differences are not minimized, and frequency may be adjusted to use control phase in a subtraction loop such as shown in FIG. 5. In this example, the system may use a nominal 2.2 GHz RF and an ADFMR sensor 505 having 330 ns of delay. The system may also include a phase and/or amplitude control 530, as described above. In such a variation, varying the frequency 9 kHz will vary the transmission phase approximately 1 degree. That means that 360 degrees of phase control can be achieved with 3.3 MHz frequency variation. The primary resonance of the ADFMR sensor may be on the order of 10 MHz wide at the 1 dB points, so this amount of frequency variation will not affect transmission amplitude significantly. As a result, frequency may be used to control phase in the subtraction loop.

A frequency modulation variation can include variable frequency excitation which functions as an effective phase shift between the reference and sensing paths. The variable frequency excitation component may be configured to tune phase shift through setting of frequency.

In some variations, this may be implemented digitally such as by including a frac-N synthesizer (e.g., discrete steps). In other variations, this may be implemented in analog using a VCO tuning voltage or other analog solution. In some variations, this may be implemented per-sensor using one or more SSB mixers and a DAC per sensor.

Implementation of a frequency modulation variation may be used in place of digital and/or analog phase shifters. This may have the potential benefit of reducing reference path noise. This may also have the potential benefit of reducing reference path loss, which may allow for unequal split to send more power to sensor.

The system may be configured for process control or laser trimming to match amplitudes between sensor and reference path. This may enable a reference path implementation with no ICs/control systems, and/or may potentially reduce reference path system complexity in order to get down to a cancellation level that may be beneficial for input to a low-frequency cancellation circuit. In some variations, e.g., with a fully on-chip SAW interferometer device, propagation speed difference between metalized (e.g., magnetic film) leg and unmetallized leg could give a similar effect and also allow for tuning.

In another variation of a fully on chip SAW interferometer device, the sensing path and reference path devices can be differentially configured as described above, where the sign of their magnetic responses are opposite (e.g., an increasing magnetic field increases signal through the sensing path while decreasing signal through the reference path). In this case, the length of the SAW delay lines could be intentionally mismatched (e.g., the sensing path ADFMR device may be 1 mm long, and the reference path ADFMR device may be 1.5 mm long) to allow for frequency tuning. The reference path is typically insensitive to the external magnetic field.

In frequency modulation variation, the system can include a fully integrated fractional-N (Frac-N) frequency synthesizer. The frequency may be set using digital control pins (e.g., sending a command to set the frequency to 2 GHz vs 2.1 GHZ) or using any suitable control input. This input changes the frequency by changing the multiplication factor of a reference oscillator. Instead of a Frac-N system, an Integer-N system could be used to reduce power consumption. As an alternative to digitally tuning the multiplication factor in the synthesizer, another variation could include tuning the reference oscillator or using a tuned reference oscillator.

In other frequency modulation variations, the system may include a voltage controlled oscillator (VCO), digitally controlled oscillator (DCO), temperature controlled oscillator (TCO) and/or an alternative type of oscillator. An oscillator such as these may be combined with an Int-N or Frac-N synthesizer or used alone.

In some examples, the system may address challenges of achieving low-noise RF signals and minimizing power-consumption. In one variation, the system may include a shared GHz oscillator (e.g., set to 2 GHz), and a sensor device having an associated mixer connected to a low frequency (e.g., MHz) tunable oscillator. In some variations, the mixer may be a single sideband (SSB) mixer. The low frequency oscillators may function to enable tuning/control, and may be much smaller/lower power than a shared GHz oscillator.

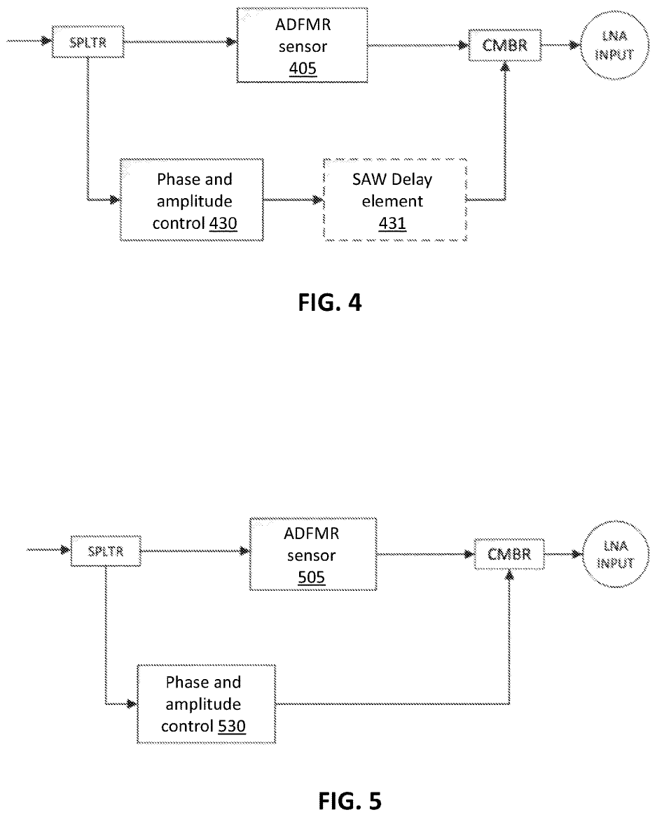

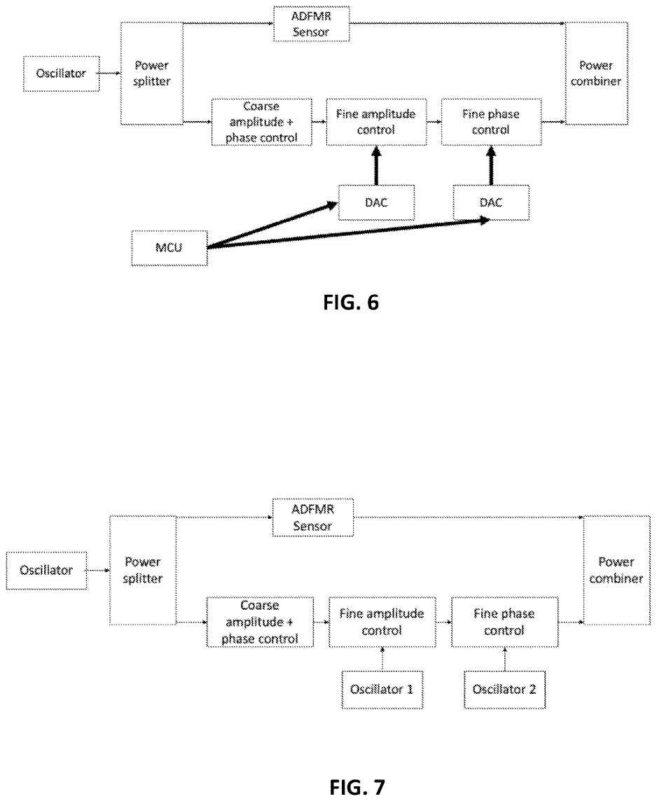

Any of these systems may be configured (e.g., including components) to use pilot tones. In such variations, the system may include one or more pilot tone generator modules, which function to apply pilot tones. The pilot tones may be tones at known frequencies in amplitude and phase. These may be used as ground truth and rotate I and Q channels to create enhanced (“ideal”) R channel and to separate signal output due to phase vs. amplitude changes in the RF signal. These may also be used to separate noise in the output signal due to phase vs. amplitude changes in the RF signal. This is extremely valuable in ADFMR sensors as most of the close-in carrier noise is due to phase noise, while the amplitude of ADFMR elements is dependent on magnetic field. Thus, through proper separation of amplitude and phase components, carrier noise can primarily be shunted to one output channel (i.e., Q), while signal is primarily shunted to the other (i.e., I). The pilot tone generator modules may be trimmers or other suitable components. In the case that a single trimmer cannot produce a suitably orthogonal modulation (in the phase/attenuation space), a modulation of two non-orthogonal trimmers can form a set of basis vectors that together can generate orthogonal modulation. Alternatively, when the rotation operation is performed in IQ space, the modulation can be rotated to the angle corresponding to the modulation's linear combination of phase and amplitude modulation, thus correcting this non-orthogonality. A pilot tone generator module may include or be integrated with existing components such as a digital-to-analog converter (DAC) that controls the analog voltage/phase trimmers which may be integrated into the system as shown in FIG. 6. The system can include an integrated microcontroller unit (MCU) that may set the details of the pilot tones. The pilot tone parameters may alternatively be set by a dedicated oscillator as shown in FIG. 7. Instead of control via trimmers, the system may use one or more frequency modulation to control phase (via the method described above) to generate a pilot tone.

In some variations of the use of a pilot tone, tones may be applied at different frequency for amplitude and phase. In some examples a pilot tone variation can work by applying a tone at different frequencies for amplitude and phase. In some variations, such tones could be Gold codes, Walsh codes, or other suitable types of orthogonal codes. A mixer used in the system may have random phase between the LO and the RF ports, such that the mixer I and Q outputs may both have some combination of tones at both the amplitude and phase frequencies. As the amplitude frequency peak should primarily show up on I, and the phase frequency peak should primarily show up on Q, a linear combination of the I and Q outputs may be applied (either in analog or digital) to end up with I′ and Q′, where I′ has only amplitude information, and Q′ has only phase information.

In another variation, the system may include modules configured for Walsh code RF subtraction. More generally this may be a form of RF subtraction that employs a code such as Walsh code to vary control signals. Such variations may be high frequency Walsh codes (e.g., outside the band of interest) and may be used to control amplitude and phase trimmers. The amplitude and phase may have distinct Walsh codes. The output of a mixer may be processed or analyzed to correlate the output with the Walsh codes and get one of the following results: correlation output is zero, correlation output is positive, or correlation output negative.

A correlation output of zero may signal that the error signal (such as residual cancelled power from a subtraction loop) is at a minimum. As a result, adjustments up and down are symmetrical, and amplitude and/or phase control may be left as is. A correlation output that is positive may signal that an increase in the control input increases the output and vice versa. The control input may then be reduced to approach a minimum error signal. The amplitude of the positive correlation may map to closeness to a minimum (e.g., smaller amplitude=closer to the minimum). A correlation output that is negative may signal that a decrease in the control input decreases the output and vice versa. The control input may be decreased to approach a minimum error signal. The amplitude of the negative correlation may map to closeness to a minimum (e.g., smaller amplitude=closer to the minimum).

For example, a system integrating Walsh code subsystem processes correlation between the input code and the output signal, with the sign (+or −) and amplitude giving information on how to adjust the cancellation parameters. The codes may appear on any channel, as the amplitude variation can be the signal used to modify operation. The amplitude variation may be detected, in one variation, from the mixer outputs (R=sqrt(I\hat{ }+Q\hat{ }2)). In another variation, the amplitude variation may be detected by measuring RF power directly before mixdown using a power detector.

When using as pilot tones, the same signals may be processed, but instead of correlating with the original, the system design can process raw amplitude and use that to rotate the I and Q channels.

Variations incorporating Walsh code processing components may be used in combination with other signal processing subsystems described herein. For example, Walsh code variations may be used in combination with RF subtraction components to use these techniques in combination in one sensor design.

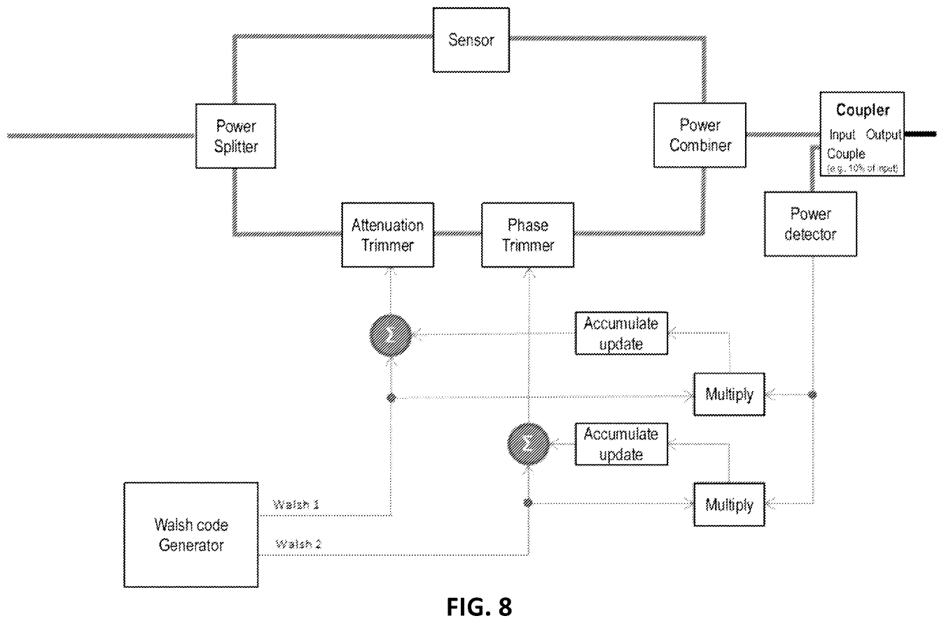

As shown in FIG. 8, a system with a Walsh code subsystem may include a Walsh code generator that applies Walsh code processed controls to phase and amplitude controls within the reference path of the sensor system. The Walsh code subsystem may be used to more dynamically adjust frequency (e.g., in order to adjust phase) and amplitude and minimize output variation. In this example the system includes a frequency modulation circuit that comprises a microcontroller configured to set a pilot tone configured as a Walsh code, as described herein, e.g., including a Walsh code generator. Any of these variations may include a power detector to detect power from the combined output signal (e.g., after combing the test/sensor signal and the demodulation signal).

In one implementation a coarse phase adjustment (e.g., within a few degrees) may be performed with frequency tuning. This may be controlled by cancelled power measurement. A phase trimmer (e.g., with +/−10 degree range) may be used for fine tracking. A high-speed tracking process or algorithm may be used. In some variations, this high-speed tracking process may be based on use of a Walsh code subsystem. A fixed attenuator (e.g., 1/4/7 dB attenuator) may be adjusted and used for coarse loss adjustment. An attenuation trimer (e.g., with 6 dB range) may be used for loss tracking. A high-speed tracking process or algorithm may similarly be used. Similar to above, the high-speed tracking process may be based on use of a Walsh code subsystem.

In one Walsh code variation, the coarse attenuation would be set with a “fixed” attenuator to match a particular sensor in use. This may be performed by matching attenuation-related components to a sensor during production, though adjustable components may be used to set a coarse attenuation after production. The goal would be to center it on the attenuation trimmer range. During operation, the coarse phase would then be set by adjusting frequency to minimize detected power. There are a few different options on how to implement this. Fine phase and attenuation adjustments using the trimmers would then run continuously at high speed, with incremental adjustments ideally made at intervals of 1 ms or less.

When a phase trimmer control approaches a limit, the coarse phase adjustment may be repeated. In some implementations, this may occur for any temperature change of 0.5 degree C or greater. In some instances, the fine adjustment of attenuation may be sufficient, regardless of temperature. With incremental phase and attenuation adjustments made at a rate greater than 1 kHz, noise introduced by these adjustments would preferably fall above the band of interest for the sensor. In such an implementation, data may be taken continuously, except during those intervals when coarse phase adjustments must be made.

Use of Walsh codes may be used to facilitate the high-speed tracking and adjustments. Walsh codes are orthogonal codes of finite length that have perfect autocorrelation and zero cross-correlation. Stated another way, any Walsh code synchronously multiplied by itself and summed over the length of the code equals the length of the code. Any Walsh code synchronously multiplied any other Walsh code of the same length and similarly summed equals zero. Walsh codes can be of any length. In one exemplary implementation a Walsh code with a length 16 may be used. The two lowest non-zero Walsh codes are square waves, the first with a bit period of T and the second with a bit period of 2T. For instance, one could be 10 kHz and the other 5 kHz. We have only two controls (phase and amplitude) so two Walsh codes are sufficient. Alternatively other types of codes may be used.

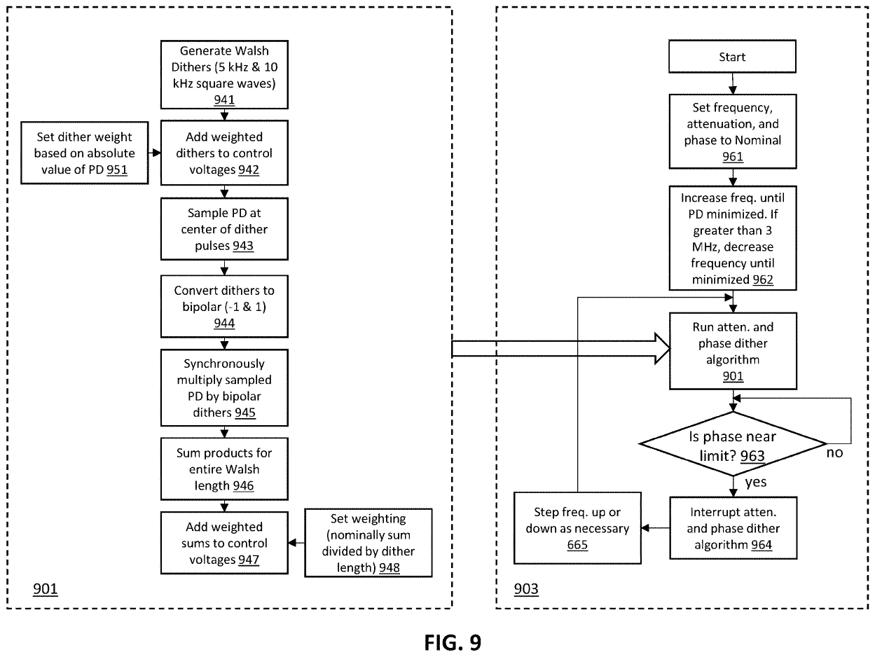

Each control (phase and attenuation) would have a very small Walsh “dither” added to it. The dither would be the applied pattern. A power detector output is preferably synchronously multiplied by bi-polar (−1,1) versions of the Walsh codes and the results summed. The summed results would be added to or subtracted from the control voltages. Thereby the control voltages for an attenuation trimmer and a phase trimmer on the reference path may be adjusted based on the control voltages. After several iterations, the control loops (phase and amplitude) will preferably converge on an optimum (or substantially enhanced) level. Once a dither results in no further improvement (no average change in the power detector), the optimum will have been reached and no correction will be made. Since the Walsh codes are orthogonal, the adjustments to phase and attenuation may be simultaneous. One potential dithering process in combination with phase reset is shown in FIG. 9.

As one potential benefit, the dither can run at frequencies above the band of interest without introduction of dither noise within that band. As another potential benefit, the speed of correction can be made fast enough to track any temperature related changes. While the phase shifter and attenuator may not be exactly orthogonal, the orthogonality of the Walsh codes reduces the impact of this substantially. Additionally, imperfections in phase and amplitude trimmers could be addressed by applying a linear combination to both to result in improved (e.g., near ideal) phase and amplitude modulation.

FIG. 9 illustrates one example of frequency tuning in an ADFMR sensor apparatus (e.g., system). In FIG. 9, the right size schematically illustrates coarse phase resetting 903, which may include calling a dither methods 901, as illustrated. In FIG. 9A, the method may be performed by any of the systems described herein, including system in which the reference path operates in parallel to the sensing (e.g., “test”) path, and in particular versions in which frequency tuning may be used. In FIG. 9, the frequency, attenuation and phase (e.g., phase to the normal) may be initially set 961, and the frequency, e.g., of the demodulation signal, may be increased 962 (using one or more oscillators, trimmers (e.g., phase trimmer, attenuation trimmer, etc.). The phase and/or frequency may be adjusted as part of a loop to achieve a target range. For example, if the frequency is greater than 3 MHZ, it may be decreased until minimized.

In any of these examples a dither technique may be used. The method may include performing an attenuation and phase dither technique 901. The dither algorithm may include generating a Walsh dither (e.g., 5 kHz and 10 kHz square waves) 941, adding weighted dithers to control the voltages 942. The dither weight may be set, e.g., based on the value 951. The method may include sampling at the center of the dither pulses 943, and converting the dithers into bipolar signals (e.g., −1 and 1) 944. The method may then synchronously multiply by the bipolar dithers 945, and may sum the products for the entire length of the Walsh code 946. These weighted sums may then be added to a control voltage 947, after the weighted sums are set (e.g., nominally the sum divided by the dither length) 948.

This process of adjusting the attenuation and/or phase dither (PD) may be continued until the phase is near a predetermined limit 963. After interruption of the attenuation and phase dither algorithm 964, the method may include stepping the frequency up or down as necessary (e.g., 10 kHz/degree) 655, and repeating the steps of running the attenuation and phase dither algorithm. The method may be performed at any appropriate update rate. For example, for a 16-bit Walsh code, the control voltage update rate may be about 1.25 kHz.

As another potential benefit, convergence to the optimum is more direct approaching more of a “straight line” convergence rather than “spiral” which is likely with non-simultaneous optimization. As another potential benefit, the simultaneous optimization greatly reduces the possibility of falling into a local rather than global minimum.

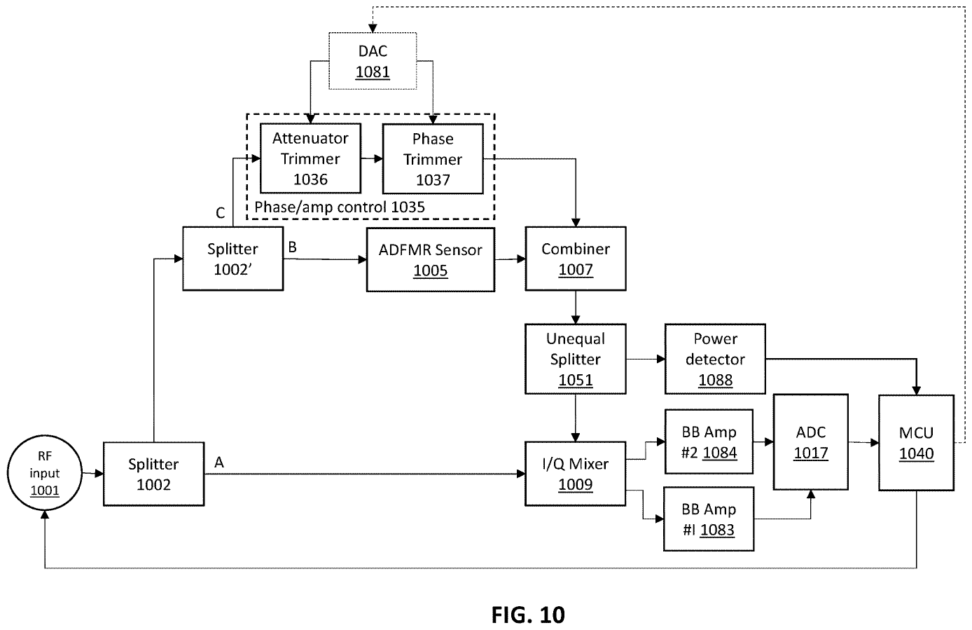

FIG. 10 illustrates another example of a system as described herein. In this example the system includes an RF input 1001 providing an input signal that is split by power splitter 1002 into the demodulation path (A) in a first branch and the second branch is again split by power splitter 1002′ into the sensing path (B) and the subtraction path (C). The sensing path includes an ADFMR sensor 1005 and the subtraction path in this example includes a phase and/or amplitude control module 1035 that may include, e.g., a phase trimmer 1036 and/or an attenuator trimmer 1037. The phase and/or amplitude control module may be modulated by a controller (e.g., DAC 1081) that may be configured as a pilot tone module, as described above. The apparatus also include a combiner 1007 for combining the signals from the sensing path, e.g., a modulated sensing signal, and the subtraction path. The demodulation pathway may also include a frequency tuning module, which may be (int his example) integrated into the microcontroller 1040, that may separately receive input on the power of subtracted sensor signal (via unequal splitter 1051 and power detector 1088). The subtracted sensor signal may also be multiplied by the demodulation signal from the demodulation path. In FIG. 10 an I/Q Mixer 1009 is shown and the I and Q channels may be separately amplified, e.g., by broadband amplifiers, 1084, 1083, respectively and this information processed by the Analog to Digital converter (ADC) 1017 and passed to the controller (MCU 1040).

All publications and patent applications mentioned in this specification are herein incorporated by reference in their entirety to the same extent as if each individual publication or patent application was specifically and individually indicated to be incorporated by reference. Furthermore, it should be appreciated that all combinations of the foregoing concepts and additional concepts discussed in greater detail below (provided such concepts are not mutually inconsistent) are contemplated as being part of the inventive subject matter disclosed herein and may be used to achieve the benefits described herein.

Any of the methods (including user interfaces) described herein may be implemented as software, hardware or firmware, and may be described as a non-transitory computer-readable storage medium storing a set of instructions capable of being executed by a processor (e.g., computer, tablet, smartphone, etc.), that when executed by the processor causes the processor to control perform any of the steps, including but not limited to: displaying, communicating with the user, analyzing, modifying parameters (including timing, frequency, intensity, etc.), determining, alerting, or the like. For example, any of the methods described herein may be performed, at least in part, by an apparatus including one or more processors having a memory storing a non-transitory computer-readable storage medium storing a set of instructions for the processes(s) of the method.

While various embodiments have been described and/or illustrated herein in the context of fully functional computing systems, one or more of these example embodiments may be distributed as a program product in a variety of forms, regardless of the particular type of computer-readable media used to actually carry out the distribution. The embodiments disclosed herein may also be implemented using software modules that perform certain tasks. These software modules may include script, batch, or other executable files that may be stored on a computer-readable storage medium or in a computing system. In some embodiments, these software modules may configure a computing system to perform one or more of the example embodiments disclosed herein.

As described herein, the computing devices and systems described and/or illustrated herein broadly represent any type or form of computing device or system capable of executing computer-readable instructions, such as those contained within the modules described herein. In their most basic configuration, these computing device(s) may each comprise at least one memory device and at least one physical processor.

The term “memory” or “memory device,” as used herein, generally represents any type or form of volatile or non-volatile storage device or medium capable of storing data and/or computer-readable instructions. In one example, a memory device may store, load, and/or maintain one or more of the modules described herein. Examples of memory devices comprise, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In addition, the term “processor” or “physical processor,” as used herein, generally refers to any type or form of hardware-implemented processing unit capable of interpreting and/or executing computer-readable instructions. In one example, a physical processor may access and/or modify one or more modules stored in the above-described memory device. Examples of physical processors comprise, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the method steps described and/or illustrated herein may represent portions of a single application. In addition, in some embodiments one or more of these steps may represent or correspond to one or more software applications or programs that, when executed by a computing device, may cause the computing device to perform one or more tasks, such as the method step.

In addition, one or more of the devices described herein may transform data, physical devices, and/or representations of physical devices from one form to another. Additionally or alternatively, one or more of the modules recited herein may transform a processor, volatile memory, non-volatile memory, and/or any other portion of a physical computing device from one form of computing device to another form of computing device by executing on the computing device, storing data on the computing device, and/or otherwise interacting with the computing device.

The term “computer-readable medium,” as used herein, generally refers to any form of device, carrier, or medium capable of storing or carrying computer-readable instructions. Examples of computer-readable media comprise, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

A person of ordinary skill in the art will recognize that any process or method disclosed herein can be modified in many ways. The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed.

The various exemplary methods described and/or illustrated herein may also omit one or more of the steps described or illustrated herein or comprise additional steps in addition to those disclosed. Further, a step of any method as disclosed herein can be combined with any one or more steps of any other method as disclosed herein.

The processor as described herein can be configured to perform one or more steps of any method disclosed herein. Alternatively or in combination, the processor can be configured to combine one or more steps of one or more methods as disclosed herein.

When a feature or element is herein referred to as being “on” another feature or element, it can be directly on the other feature or element, or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Terminology used herein is for the purpose of describing particular embodiments only and is not intended to be limiting of the invention. For example, as used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. As used herein, the term “and/or” includes any and all combinations of one or more of the associated listed items and may be abbreviated as “/”.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under”, or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

Although the terms “first” and “second” may be used herein to describe various features/elements (including steps), these features/elements should not be limited by these terms, unless the context indicates otherwise. These terms may be used to distinguish one feature/element from another feature/element. Thus, a first feature/element discussed below could be termed a second feature/element, and similarly, a second feature/element discussed below could be termed a first feature/element without departing from the teachings of the present invention.

In general, any of the apparatuses and methods described herein should be understood to be inclusive, but all or a sub-set of the components and/or steps may alternatively be exclusive and may be expressed as “consisting of” or alternatively “consisting essentially of” the various components, steps, sub-components or sub-steps.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical values given herein should also be understood to include about or approximately that value, unless the context indicates otherwise. For example, if the value “10” is disclosed, then “about 10” is also disclosed. Any numerical range recited herein is intended to include all sub-ranges subsumed therein. It is also understood that when a value is disclosed that “less than or equal to” the value, “greater than or equal to the value” and possible ranges between values are also disclosed, as appropriately understood by the skilled artisan. For example, if the value “X” is disclosed the “less than or equal to X” as well as “greater than or equal to X” (e.g., where X is a numerical value) is also disclosed. It is also understood that the throughout the application, data is provided in a number of different formats, and that this data, represents endpoints and starting points, and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

Although various illustrative embodiments are described above, any of a number of changes may be made to various embodiments without departing from the scope of the invention as described by the claims. Optional features of various device and system embodiments may be included in some embodiments and not in others. Therefore, the foregoing description is provided primarily for exemplary purposes and should not be interpreted to limit the scope of the invention as it is set forth in the claims.

The examples and illustrations included herein show, by way of illustration and not of limitation, specific embodiments in which the subject matter may be practiced. As mentioned, other embodiments may be utilized and derived there from, such that structural and logical substitutions and changes may be made without departing from the scope of this disclosure. Such embodiments of the inventive subject matter may be referred to herein individually or collectively by the term “invention” merely for convenience and without intending to voluntarily limit the scope of this application to any single invention or inventive concept, if more than one is, in fact, disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

1. A system for an acoustically driven ferromagnetic resonance (ADFMR) based measurement of electromatic (EM) fields, the system comprising:
a power splitter configured to split a high frequency electrical signal into a sensing signal and a demodulation signal;
an ADFMR sensor comprising a first electrical transducer coupled to a piezoelectric substrate and configured to receive the sensing signal, a magnetostrictive material on the substrate, and a second electrical transducer coupled to the piezoelectric substrate and configured to output a modulated sensing signal;
a mixer configured to combine a signal from the modulated sensing signal with the demodulation signal, the mixer having an output;
a low-frequency cancellation sub-system coupled to the output of the mixer and configured to remove a DC or near-DC voltage component of the output of the mixer; and
a detector that determines the EM field from the output after low-frequency cancellation.

2. The system of claim 1, further comprising a power source comprising an oscillator configured to provide the electrical signal to the power splitter.

3. The system of claim 1, wherein the low-frequency cancellation sub-system comprises a set of baseband amplifiers coupled to an I channel and a Q channel of the mixer.

4. The system of claim 3, wherein the low-frequency cancellation sub-system is configured to sample the output of the baseband amplifiers and apply a correction signal to the inputs of the baseband amplifiers to null the output voltages.

5. The system of claim 1 wherein the low-frequency cancellation sub-system comprises a set of lowpass filters and baseband amplifiers coupled to an I channel and a Q channel of the mixer.

6. The system of claim 1, wherein the low-frequency cancellation sub-system comprises a reset function configured to zero an output of the low-frequency cancellation sub-system within less than 10 milliseconds.

7. The system of claim 1, wherein the low-frequency cancellation sub-system comprises a microprocessor configured to adjust a cut-off frequency of the low-frequency cancellation sub-system.

8. The system of claim 1, wherein the low-frequency cancellation sub-system is configured to move frequencies of less than 0.5 Hz from the output of the mixer.

9. The system of claim 1, wherein the low-frequency cancellation sub-system comprises an adjustable capacitance and/or a resistance configured to be adjusted to zero a low-frequency output.

10. A system for an acoustically driven ferromagnetic resonance (ADFMR) based measurement of electromatic (EM) fields, the system comprising:
a high-frequency electrical oscillator;
a first power splitter configured to split a high frequency electrical signal from the high-frequency electrical oscillator between a demodulation path and a second power splitter;
wherein the second power splitter is configured to further split the high-frequency electrical signal from the first power splitter between a sensing path and a subtraction path;
an ADFMR sensor in the sensing path, the ADFMR sensor comprising a first electrical transducer coupled to a piezoelectric substrate and configured to receive a sensing signal, a magnetostrictive material on the substrate, and a second electrical transducer coupled to the piezoelectric substrate and configured to output a modulated sensing signal;
a combiner combining the modulated sensing signal from the sensing path and a signal from the subtraction path;
a mixer configured to combine an output of the combiner with an output of the demodulation path;
a frequency tuning module in communication with the high-frequency electrical oscillator and configured to modulate the high-frequency electrical oscillator; and
a detector that determines the EM field from an output of the mixer.

11. The system of claim 10, wherein the high-frequency electrical oscillator is a radio-frequency (RF) oscillator.

12. The system of claim 10, wherein the frequency tuning module receives control input from a controller.

13. The system of claim 10, wherein the frequency tuning module is configured to adjust the phase of the signal from the subtraction path by adjusting the frequency of the high-frequency oscillator.

14. The system of claim 10, further comprising a low-frequency cancellation module between the mixer and the detector.

15. The system of claim 10, further comprising a phase and/or amplitude control module in the sensing path or the subtraction path, wherein the phase and/or amplitude control module is configured to adjust phase and/or amplitude of the sensing path or the subtraction path.

16. The system of claim 10, further comprising a phase and/or amplitude control module in the subtraction path, wherein the phase and/or amplitude control module is configured to adjust phase and/or amplitude of the signal from the subtraction path.

17. The system of claim 15, wherein the phase and/or amplitude control module comprises an attenuator trimmer and a phase trimmer.

18. The system of claim 15, further comprising a pilot tone module in communication with the phase and/or amplitude control module, wherein the pilot tone module is configured to apply one or more pilot tones to an attenuator trimmer and a phase trimmer of the phase and/or amplitude control module.

19. The system of claim 18, wherein the pilot tone module is configured to apply an orthogonal code.

20. The system of claim 18, wherein the orthogonal code comprises a Walsh code.

21. The system of claim 18, further comprising a power detector downstream of the combiner and configured to adjust the pilot tone module.

22.-34. (canceled)
